(19) United States
(12) Patent Application Publication
(10) Pub. No.: US 2025/0140727 A1
(43) Pub. Date: May 1, 2025

(54) WIRING STRUCTURE, SEMICONDUCTOR PACKAGE COMPRISING THE SAME, AND METHOD OF MANUFACTURING THE SAME

(71) Applicant: Samsung Electronics Co., Ltd., Suwon-si (KR)

(72) Inventors: Wonbin Shin, Suwon-si (KR); Jihye Shim, Suwon-si (KR); Seokkyu Lee, Suwon-si (KR)

(21) Appl. No.: 18/891,191

(22) Filed: Sep. 20, 2024

(30) Foreign Application Priority Data
Oct. 25, 2023 (KR) 10-2023-0144172

(51) Int. Cl. H01L 23/00; H01L 23/31; H01L 23/49

(52) U.S. Cl. CPC H01L 24/20; H01L 23/49; H01L 23/3107; H01L 2224/2101; H01L 2224/214; H01L 2224/215; H01L 2224/221

(57) ABSTRACT

Provided is a wiring structure including a wiring insulating layer including a first insulating layer and a second insulating layer on the first insulating layer, and a wiring pattern that penetrates the second insulating layer and extends into the first insulating layer, wherein a portion of a side surface of the wiring pattern in contact with the first insulating layer is a curved surface with a first surface roughness, and a portion of the side surface of the wiring pattern in contact with the second insulating layer is a flat surface with a second surface roughness that is less than the first surface roughness.

### CROSS-REFERENCE TO RELATED APPLICATION

This application is based on and claims priority under 35 U.S.C. § 119 to Korean Patent Application No. 10-2023-0144172, filed on Oct. 25, 2023, in the Korean Intellectual Property Office, the disclosure of which is incorporated by reference herein in its entirety.

### BACKGROUND

The inventive concept relates to a wiring structure, a semiconductor package including the same, and a method of manufacturing the same.

In accordance with the development of the electronics industry and consumer demands, electronic devices are gradually becoming smaller, more multi-functional, and larger in capacity. Accordingly, a semiconductor package including a redistribution structure is being developed for a highly integrated semiconductor chip with an increased number of connection terminals for data input/output (I/O). As line widths of wiring patterns included in the redistribution structure diversify and the minimum line widths in the wiring patterns decrease, there is a need to develop technology to ensure the reliability of the wiring patterns with various line widths included in the redistribution structure.

### SUMMARY

The inventive concept provides a wiring structure with improved structural reliability, a semiconductor package including the same, and a method of manufacturing the same.

According to some embodiments of the inventive concept, there is provided a wiring structure including a wiring insulating layer including a first insulating layer and a second insulating layer on the first insulating layer, and a wiring pattern that penetrates the second insulating layer and extends into the first insulating layer, wherein a portion of a side surface of the wiring pattern in contact with the first insulating layer is a curved surface with a first surface roughness, and a portion of the side surface of the wiring pattern in contact with the second insulating layer is a flat surface with a second surface roughness that is less than the first surface roughness.

According to some embodiments of the inventive concept, there is provided a semiconductor package including a first redistribution structure including a first redistribution insulating layer and a first redistribution pattern, a semiconductor chip on the first redistribution structure, and a second redistribution structure on the semiconductor chip and includes a second redistribution insulating layer including a first insulating layer and a second insulating layer on the first insulating layer, and a second redistribution pattern that penetrates the second insulating layer and extends into the first insulating layer, wherein a portion of a side surface of the second redistribution pattern in contact with the first insulating layer is a curved surface with a first surface roughness, and a portion of the side surface of the second redistribution pattern in contact with the second insulating layer is a flat surface with a second surface roughness that is less than the first surface roughness.

According to some embodiments of the inventive concept, there is provided a semiconductor package including a first redistribution structure including a first redistribution insulating layer and a first redistribution pattern, a semiconductor chip on the first redistribution structure, a connection structure on the first redistribution structure and on side surfaces of the semiconductor chip, a molding layer that at least partially fills a space between the semiconductor chip and the connection structure and is on a top surface of each of the semiconductor chip and the connection structure, and a second redistribution structure on the semiconductor chip and includes a second redistribution insulating layer including a first insulating layer and a second insulating layer on the first insulating layer, and a second redistribution pattern that penetrates the second insulating layer and extends into the first insulating layer, wherein a portion of a side surface of the second redistribution pattern in contact with the first insulating layer is a curved surface with a first surface roughness, and a portion of the side surface of the second redistribution pattern in contact with the second insulating layer is a flat surface with a second surface roughness that is less than the first surface roughness.

### BRIEF DESCRIPTION OF THE DRAWINGS

Embodiments will be more clearly understood from the following detailed description taken in conjunction with the accompanying drawings in which:

FIG. 1 is a perspective view of a build-up film according to some embodiments;

FIG. 2A is a cross-sectional view of a semiconductor package according to some embodiments, and FIG. 2B is an enlarged cross-sectional view of portion EX of FIG. 2A;

FIG. 3A is a cross-sectional view of a semiconductor package according to some embodiments, and FIG. 3B is an enlarged cross-sectional view of portion EX′ of FIG. 3A;

FIG. 4 is a cross-sectional view of a semiconductor package according to some embodiments;

FIGS. 5A, 5B, 5C, and 5D are cross-sectional views illustrating a method of manufacturing a semiconductor package, according to some embodiments; and

FIGS. 6A, 6B, 6C, 6D, 6E, 6F, 6G, 6H, and 6I are enlarged cross-sectional views illustrating a method of manufacturing a second redistribution structure included in a semiconductor package.

### DETAILED DESCRIPTION

Hereinafter, embodiments are described in detail with reference to the attached drawings. The same reference numerals are used for the same components in the drawings, and duplicate descriptions thereof are omitted.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

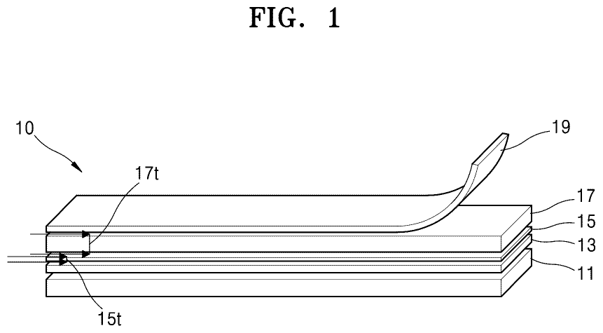

FIG. 1 is a perspective view of a build-up film 10 according to some embodiments.

Referring to FIG. 1, the build-up film 10 may include a support film 11, a release layer 13, a protective layer 15, an insulating resin layer 17, and a protective film 19. The release layer 13, the protective layer 15, the insulating resin layer 17, and the protective film 19 may each be sequentially laminated on the support film 11. The support film 11, the release layer 13, the protective layer 15, the insulating resin layer 17, and the protective film 19 may each have substantially the same horizontal area. The build-up film 10 may be used to form a printed circuit board (PCB) or a wiring structure, such as a redistribution structure included in a semiconductor package.

The support film 11 may support the release layer 13, the protective layer 15, and the insulating resin layer 17, each formed on the support film 11. In some embodiments, the support film 11 may include a material having a glass transition temperature of about 200° C. or higher. For example, the support film 11 may include polyimide (PI), colorless polyimide (CPI), etc.

The release layer 13 may be disposed on the support film 11. In some embodiments, the release layer 13 may have a thickness or vertical length of about 1 μm or less. For example, the release layer 13 may have a thickness or vertical length of about 0.5 μm.

The protective layer 15 may be disposed on the release layer 13. The protective layer 15 may prevent surface roughness from being formed by a desmear process on a surface of a redistribution insulating layer formed by the insulating resin layer 17 in a process of manufacturing the semiconductor package by using the build-up film 10. In some embodiments, the protective layer 15 may include an inorganic material. In some embodiments, the protective layer 15 may include an inorganic insulating material. For example, the protective layer 15 may include silicon oxide, silicon nitride, silicon oxynitride, or a combination thereof. In some embodiments, the protective layer 15 may have a thickness or a vertical length 15t of about 10 nm to about 5000 nm in a direction perpendicular to the support film 11. For example, the protective layer 15 may have a thickness or vertical length 15t of about 1000 nm in a direction parallel to the support film 11. In some embodiments, the protective layer 15 may be formed by chemical vapor deposition (CVD). For example, the protective layer 15 may be formed by low pressure chemical vapor deposition (LPCVD) or plasma enhanced chemical vapor deposition (PECVD).

The insulating resin layer 17 may be disposed on the protective layer 15. The insulating resin layer 17 may form the redistribution insulating layer of the redistribution structure included in the semiconductor package in the process of manufacturing the semiconductor package by using the build-up film 10. In some embodiments, the insulating resin layer 17 may include an organic material. For example, the insulating resin layer 17 may include an organic insulating material. In some embodiments, the insulating resin layer 17 may include thermosetting resin. For example, the insulating resin layer 17 may include epoxy resin. In some embodiments, the insulating resin layer 17 may have a thickness or vertical length 17t of about 50 μm to about 60 μm in a direction perpendicular to the support film 11. For example, the insulating resin layer 17 may have a thickness or vertical length 17t of about 55 μm.

The protective film 19 may be disposed on the insulating resin layer 17. The protective film 19 may prevent contamination of the insulating resin layer 17 by covering or overlapping the insulating resin layer 17. The protective film 19 may include, for example, polyethylene, polypropylene, stretched polypropylene, polyvinyl chloride, polyethylene terephthalate, and/or the like. In some embodiments, the protective film 19 may have a thickness or vertical length of about 10 μm to about 20 μm in a direction perpendicular to the support film 11. For example, the protective film 19 may have a thickness or vertical length of about 15 μm.

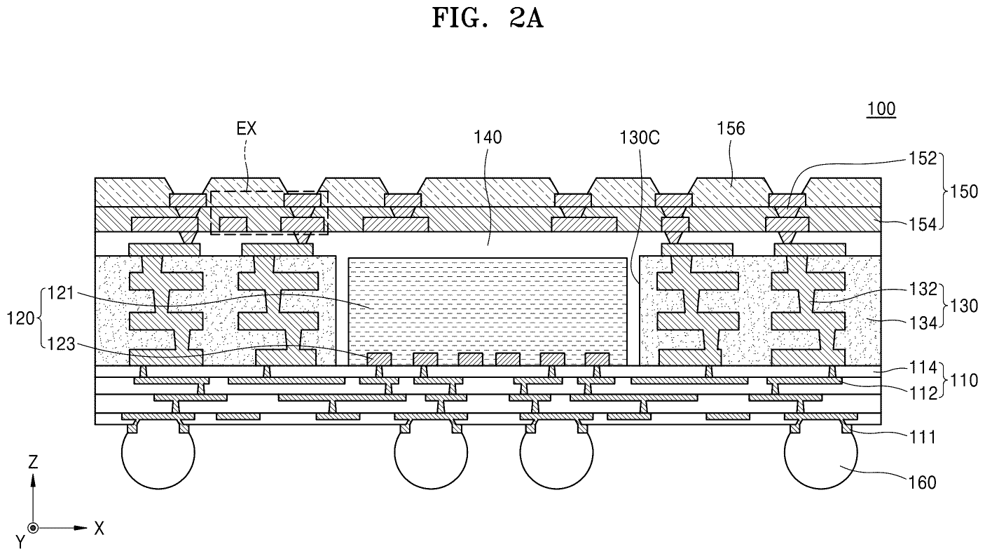

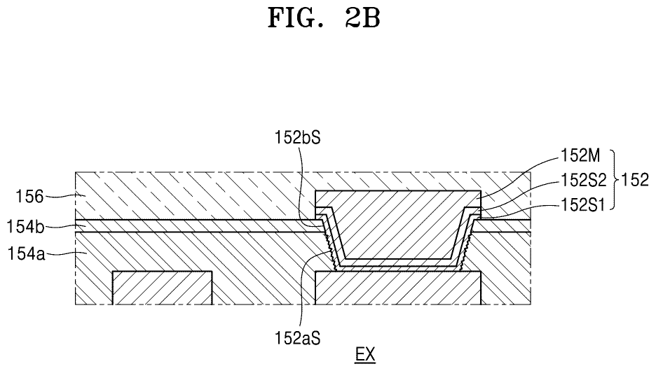

FIG. 2A is a cross-sectional view of a semiconductor package 100 according to some embodiments, and FIG. 2B is an enlarged cross-sectional view of portion EX of FIG. 2A.

Referring to FIGS. 2A and 2B, the semiconductor package 100 may include a first redistribution structure 110, a semiconductor chip 120, a connection structure 130, a molding layer 140, and a second redistribution structure 150.

In some embodiments, the semiconductor package 100 may be a fan-out semiconductor package in which the footprint of the first redistribution structure 110 is greater than the footprint of the semiconductor chip 120. For example, the semiconductor package 100 may be a fan-out semiconductor package having a fan-out panel level package (FOPLP) structure.

The first redistribution structure 110 may include first redistribution patterns 112 and a first redistribution insulating layer 114. The first redistribution insulating layer 114 may include a plurality of insulating layers stacked in a vertical direction (Z direction), but is not limited thereto. Unlike illustrated in FIG. 2A, the first redistribution insulating layer 114 may include a single insulating layer. In some embodiments, the first redistribution insulating layer 114 may include photo image-able dielectric (PID), Ajinomoto build-up film (ABF), solder resist (SR), epoxy molding compound (EMC), FR-4, bismaleimide triazine (BT), or a combination thereof.

The first redistribution patterns 112 may be covered or overlapped by the first redistribution insulating layer 114. The first redistribution pattern 112 may include a plurality of first redistribution lines and a plurality of first redistribution vias. The first redistribution lines may extend, within the first redistribution insulating layer 114, in a horizontal direction parallel to a top surface of the first redistribution insulating layer 114. Some of the first redistribution lines may be at different vertical levels (e.g., distance from the semiconductor chip 120) from the other first redistribution lines. The first redistribution vias may extend, within the first redistribution insulating layer 114, in the vertical direction (Z direction) perpendicular to the top surface of the first redistribution insulating layer 114. The first redistribution vias may connect the first redistribution lines located at different vertical levels to each other, may connect some of uppermost first redistribution lines among the first redistribution lines to the semiconductor chip 120, or may connect some of uppermost first redistribution lines among the first redistribution lines to the connection structure 130. For example, the first redistribution vias may have a tapered shape in which the horizontal width thereof increases in a direction from a top surface of the first redistribution structure 110 to a bottom surface of the first redistribution structure 110.

In some embodiments, the first redistribution patterns 112 may include copper (Cu), titanium (Ti), titanium tungsten (TiW), titanium nitride (TiN), tantalum (Ta), tantalum nitride (TaN), chromium (Cr), and aluminum (Al), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

A plurality of Under Bump Metallization, UBM layers 111 may be disposed on bottom surfaces of the lowermost first redistribution patterns 112. A portion of side surfaces of each of the plurality of UBM layers 111 may be covered by or overlapped by the first redistribution insulating layer 114. Each of the plurality of UBM layers 111 may include, for example, Cu. In some embodiments, the UBM layers 111 may be omitted.

External connection terminals 160 may be disposed on the UBM layers 111. The external connection terminals 160 may be in contact with the UBM layers 111. In some embodiments, the external connection terminals 160 may include Sn, silver (Ag), Cu, Ni, or a combination thereof. In some embodiments, the external connection terminals 160 may include solder balls.

The semiconductor chip 120 may be disposed on the first redistribution structure 110. The semiconductor chip 120 may be configured to receive at least one of a control signal, a power signal, and/or a ground signal for the operation of the semiconductor chip 120 from the outside through the first redistribution structure 110, or to provide data stored in the semiconductor chip 120 to the outside.

The semiconductor chip 120 may include, for example, a logic chip or a memory chip. The logic chip may be a microprocessor. For example, the logic chip may be a central processing unit (CPU), a controller, an application specific integrated circuit (ASIC), or the like. The memory chip may be a volatile memory chip, such as dynamic random access memory (DRAM) or static random access memory (SRAM), or a nonvolatile memory chip, such as phase-change random access memory (PRAM), magnetoresistive random access memory (MRAM), ferroelectric random access memory (FeRAM), or resistive random access memory (RRAM).

The semiconductor chip 120 may include a semiconductor substrate 121 and chip pads 123. The semiconductor substrate 121 may include a semiconductor element, such as Si or Ge, or a compound semiconductor, such as SiC, GaAs, InAs, InP, or the like. The semiconductor substrate 121 may include a conductive region, for example, an impurity-doped well or an impurity-doped structure. The semiconductor substrate 121 may have various device isolation structures such as a shallow trench isolation (STI) structure.

The semiconductor substrate 121 may include an active surface and an inactive surface facing the active surface. For example, the active surface of the semiconductor substrate 121 may be a bottom surface of the semiconductor substrate 121 on which the chip pads 123 are disposed, and the inactive surface of semiconductor substrate 121 may be a top surface of the semiconductor substrate 121 facing the bottom surface of the semiconductor substrate 121.

The active surface of the semiconductor substrate 121 may include various types of individual devices. For example, the individual devices may include various micro-electronic devices, such as complementary metal-oxide semiconductor (CMOS) transistors, metal-oxide-semiconductor filed effect transistors (MOSFETs), system large scale integration (LSI), image sensors such as a CMOS imaging sensor (CIS), micro-electro-mechanical system (MEMS), active devices, and/or passive devices.

The individual devices may be electrically connected to the conductive region of the semiconductor substrate 121. Each of the individual devices may be electrically insulated from other neighboring individual devices by an insulating layer (not shown).

The chip pads 123 may be disposed on the bottom surface of the semiconductor substrate 121. The chip pads 123 may be electrically connected to various types of individual devices included in the active surface the semiconductor substrate 121.

The connection structure 130 may be disposed on the first redistribution structure 110. The connection structure 130 may have a cavity 130C in the central area of the connection structure 130 in which the semiconductor chip 120 is mounted. The connection structure 130 may horizontally surround or be on a sidewall of the semiconductor chip 120, and inner surfaces of the connection structure 130 may be horizontally spaced apart from side surfaces of the semiconductor chip 120.

The connection structure 130 may be a PCB, a ceramic substrate, a wafer for package manufacturing, or an interposer. For example, the connection structure 130 may be a multi-layer PCB.

The connection structure 130 may include connection patterns 132 and a base layer 134. The base layer 134 may include a plurality of base layers stacked in the vertical direction (Z direction). For example, the base layer 134 may include three base layers stacked in the vertical direction (Z direction), as illustrated in FIGS. 2A and 2B, but is not limited thereto. In some embodiments, the base layer 134 may include prepreg, ABF, frame retardant 4 (FR4), tetrafunctional epoxy, polyphenylene ether, BT, epoxy/polyphenylene oxide, Thermount, cyanate ester, PI, liquid crystal polymer, or a combination thereof.

At least a portion of the connection pattern 132 may be covered or overlapped by the base layer 134. The connection pattern 132 may include a plurality of connection pads and a plurality of connection vias. The connection pads may extend in the horizontal direction on a top surface or a bottom surface of the base layer 134. Some of the connection pads may be at different vertical levels from the other connection pads. Some uppermost connection pads among the connection pads may be covered or overlapped by the molding layer 140.

The connection vias may extend in the vertical direction (Z direction) within the base layer 134. The connection vias may connect the connection pads located at different vertical levels to each other. For example, the connection vias may have a tapered shape in which the horizontal width thereof increases in a direction from a bottom surface of the semiconductor chip 120 to a top surface of the semiconductor chip 120.

In some embodiments, the connection patterns 132 may include Cu, Ni, stainless steel, BeCu, or a combination thereof.

The molding layer 140 may at least partially fill a space between the base layer 134 and the semiconductor chip 120 in the cavity 130C and may cover or overlap a top surface of each of the connection structure 130 and the semiconductor chip 120. In some embodiments, the molding layer 140 may include an epoxy-based material, a thermosetting material, or a thermoplastic material. For example, the molding layer 140 may include ABF, FR-4, BT, EMC, or a combination thereof.

The second redistribution structure 150 may be disposed above the semiconductor chip 120. The footprint of the second redistribution structure 150 may be greater than the footprint of the semiconductor chip 120. Additionally, the footprint of the second redistribution structure 150 may be substantially the same as the footprint of the first redistribution structure 110, but is not limited thereto.

The second redistribution structure 150 may include second redistribution patterns 152 (also referred to as a wiring pattern) and a second redistribution insulating layer 154.

The second redistribution insulating layer 154 (also referred to as a wiring insulating layer) may include a first insulating layer 154a and a second insulating layer 154b. The first insulating layer 154a may be an insulating layer formed by using the insulating resin layer 17 of the build-up film 10 illustrated in FIG. 1, and the second insulating layer 154b may be an insulating layer formed by using the protective layer 15 of the build-up film 10 illustrated in FIG. 1. Accordingly, the first insulating layer 154a may include substantially the same material as the insulating resin layer 17 (see FIG. 1) of the build-up film 10, and the second insulating layer 154b may include substantially the same material as the protective layer 15 (see FIG. 1) of the build-up film 10. For example, the first insulating layer 154a may include an organic material such as epoxy resin, and the second insulating layer 154b may include an inorganic material such as silicon oxide.

In some embodiments, the first insulating layer 154a may have a thickness or vertical length of about 50 μm to about 60 μm, and the second insulating layer 154b may have a thickness or vertical length of about 10 nm to about 5000 nm. That is, the thickness or vertical length of the first insulating layer 154a is substantially the same as the thickness or vertical length of the insulating resin layer 17 of the build-up film 10 illustrated in FIG. 1, and the thickness or vertical length of the second insulating layer 154b may be substantially the same as the thickness or vertical length of the protective layer 15.

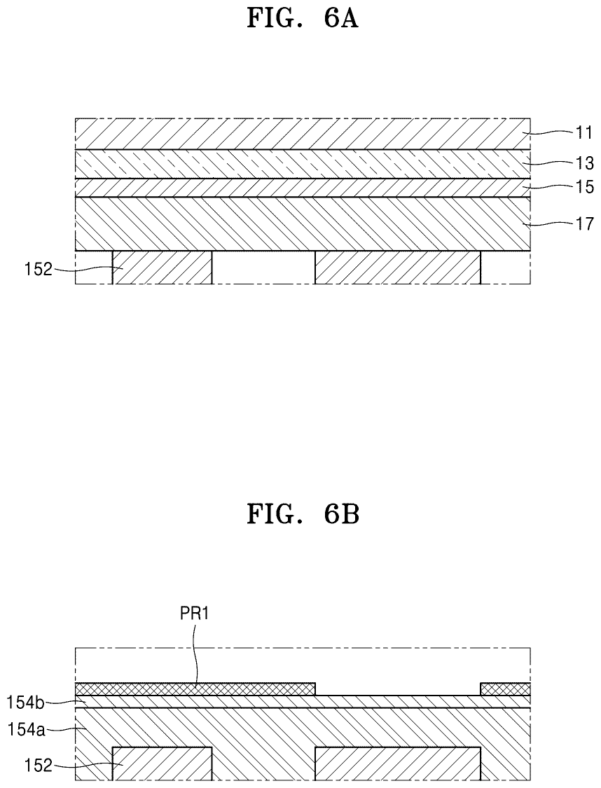

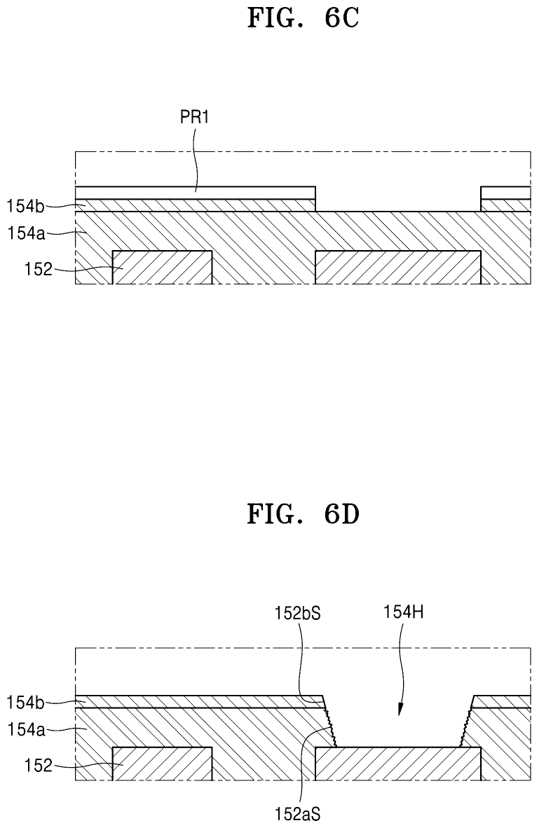

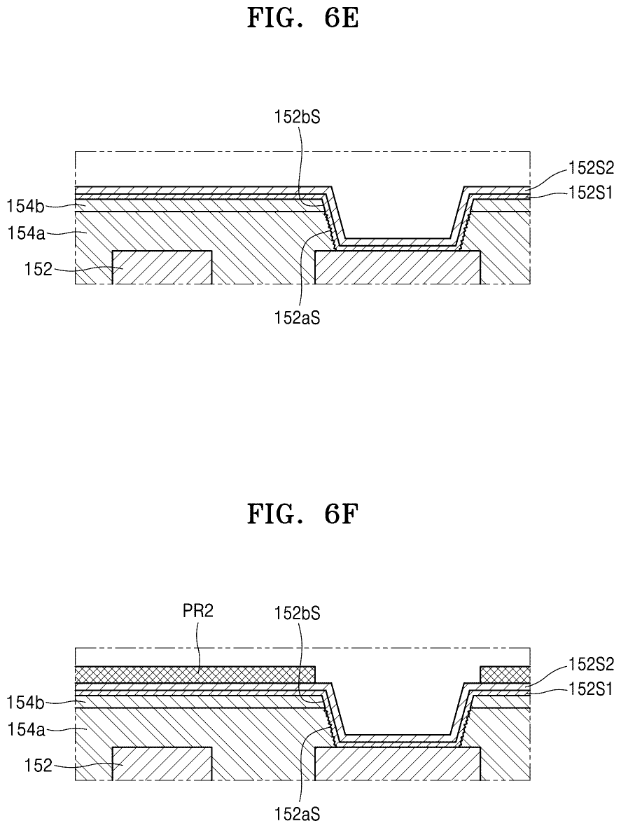

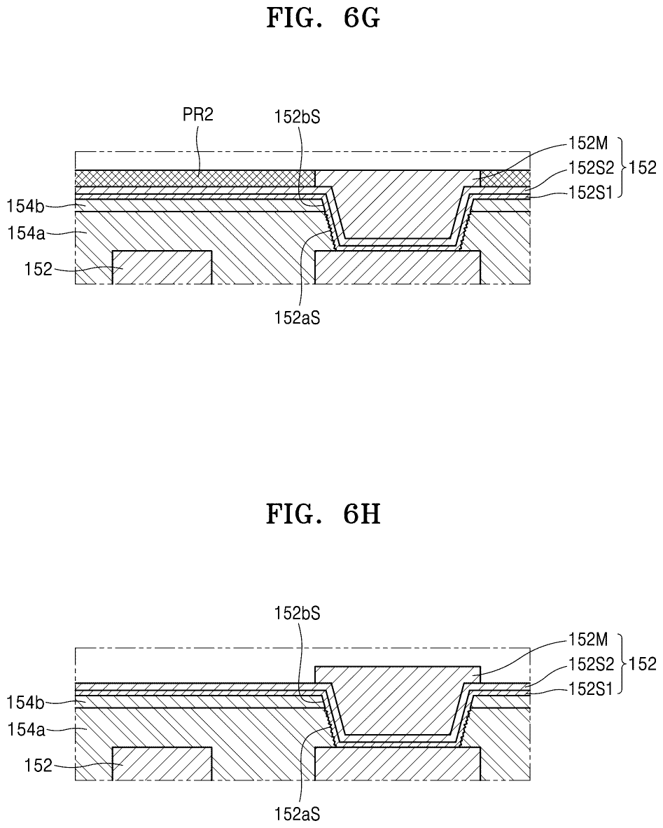

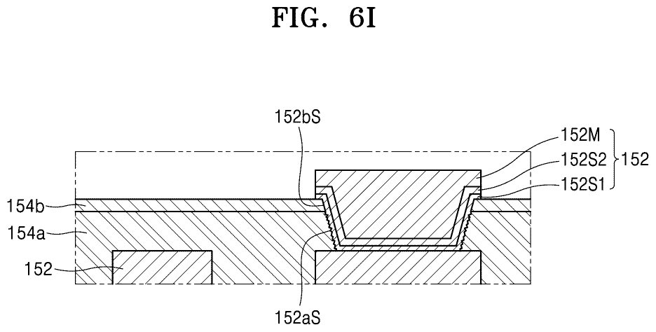

In some embodiments, a top surface of the first insulating layer 154a may be a flat surface without surface roughness (e.g., smooth). As used herein “without surface roughness” may mean that the surface is smooth, or with a surface roughness that is relatively less than the surface roughness of other elements. This may be because, when performing the desmear process to be described below with reference to FIG. 6D, the top surface of the first insulating layer 154a is not etched by the desmear process as the second insulating layer 154b including an inorganic material covers or overlaps the top surface of the first insulating layer 154a including an organic material.

In some embodiments, a top surface of the second insulating layer 154b may be a flat surface without surface roughness (e.g., smooth, or with a surface roughness that is relatively less than the surface roughness of other elements). This may be because the second insulating layer 154b includes an inorganic material, and thus the surface of the second insulating layer 154b is not etched by the desmear process to be described below with reference to FIG. 6D.

In FIGS. 2A and 2B, the second redistribution insulating layer 154 is illustrated as being composed of one insulating layer including the first insulating layer 154a, which includes a single layer, and the second insulating layer 154b, which includes a single layer, but is not limited thereto. For example, unlike illustrated in FIGS. 2A and 2B, the second redistribution insulating layer 154 may have a structure in which insulating layers including the first insulating layer 154a, which includes a single layer, and the second insulating layer 154b, which includes a single layer, are stacked.

The second redistribution pattern 152 may include a plurality of second redistribution lines and a plurality of second redistribution vias. The second redistribution lines may extend in the horizontal direction (X direction) on a top surface or a bottom surface of the second redistribution insulating layer 154. Some of the second redistribution lines may be at different vertical levels (i.e, height or perpendicular distance from the semiconductor substrate 121) from the other second redistribution lines.

The second redistribution vias may extend in the vertical direction (Z direction) within the second redistribution insulating layer 154. For example, the second redistribution vias may penetrate the second insulating layer 154b in the vertical direction (Z direction) and may extend into the first insulating layer 154a. The second redistribution vias may contact each of the first insulating layer 154a and the second insulating layer 154b on both sides. The second redistribution vias may connect the second redistribution lines located at different vertical levels (i.e, height or perpendicular distance from the semiconductor substrate 121) to each other, or may connect some of lowermost second redistribution lines among the second redistribution lines to the connection structure 130. For example, the second redistribution vias may have a tapered shape in which the horizontal width thereof increases in a direction from a bottom surface of the second redistribution structure 150 to a top surface of the second redistribution structure 150.

In some embodiments, a portion 152aS of the side surface of the second redistribution pattern 152 in contact with the first insulating layer 154a may be a curved surface with surface roughness. For example, a portion of the side surface of the second redistribution via included in the second redistribution pattern 152 in contact with the first insulating layer 154a may be a curved surface with surface roughness. In some embodiments, the other portion 152bS of the side surface of the second redistribution pattern 152 in contact with the second insulating layer 154b may be a flat surface without surface roughness (e.g., smooth). For example, a portion of the side surface of the second redistribution via included in the second redistribution pattern 152 in contact with the second insulating layer 154b may be a flat surface without surface roughness (e.g., smooth). This may be because, when performing the desmear process to be described below with reference to FIG. 6D, the surface of the first insulating layer 154a including an organic material is etched, but the surface of the second insulating layer 154b including an inorganic material is not etched.

The second redistribution pattern 152 may include a first seed layer 152S1, a second seed layer 152S2, and a metal layer 152M. The first seed layer 152S1 may cover or overlap a portion of the surface of each of the first insulating layer 154a and the second insulating layer 154b. The first seed layer 152S1 may include, for example, Ti. The second seed layer 152S2 may be formed on the first seed layer 152S1 and may cover or overlap the first seed layer 152S1. The metal layer 152M may be formed on the second seed layer 152S2 and may cover or overlap the second seed layer 152S2. The second seed layer 152S2 and the metal layer 152M may each include Cu. A portion of each of the first seed layer 152S1, the second seed layer 152S2, and the metal layer 152M may form the second redistribution via of the second redistribution pattern 152, and the other portion of each of the first seed layer 152S1, the second seed layer 152S2, and the metal layer 152M may form the second redistribution line of the second redistribution pattern 152.

An upper insulating layer 156 may be disposed on the second redistribution structure 150. The upper insulating layer 156 may cover or overlap a portion of each of the second redistribution insulating layer 154 and the second redistribution patterns 152. The upper insulating layer 156 may have a plurality of holes that overlap the second redistribution patterns 152 in the vertical direction (Z direction). When the semiconductor package 100 illustrated in FIGS. 2A and 2B is a lower semiconductor package that is a package on package (POP) type semiconductor package, a plurality of external connection terminals (not shown) may be placed on the plurality of holes, respectively, to connect an upper package to the lower package constituting the PoP type semiconductor package.

According to some embodiments, the semiconductor package 100 may include the second redistribution structure 150 including the second redistribution patterns 152 and the second redistribution insulating layer 154, and the second redistribution insulating layer 154 may include the first insulating layer 154a including an organic material and the second insulating layer 154b including an inorganic material and disposed on the first insulating layer 154s. Since the second redistribution insulating layer 154 includes the second insulating layer 154b including an inorganic material with a relatively low thermal expansion coefficient, the difference in thermal expansion coefficient between the second redistribution structure 150 and the semiconductor chip 120 may be reduced. In addition, since the second redistribution insulating layer 154 includes the second insulating layer 154b including an inorganic material, the metal material forming the second redistribution patterns 152 may be prevented from migration due to moisture absorption. Additionally, since the second insulating layer 154b covers or overlaps a portion of the surface of the first insulating layer 154a, surface roughness may be prevented from being formed on the surface of the first insulating layer 154a by the desmear process. Accordingly, in a process of forming the second redistribution patterns 152 after the desmear process is performed, fine second redistribution patterns 152 may be implemented.

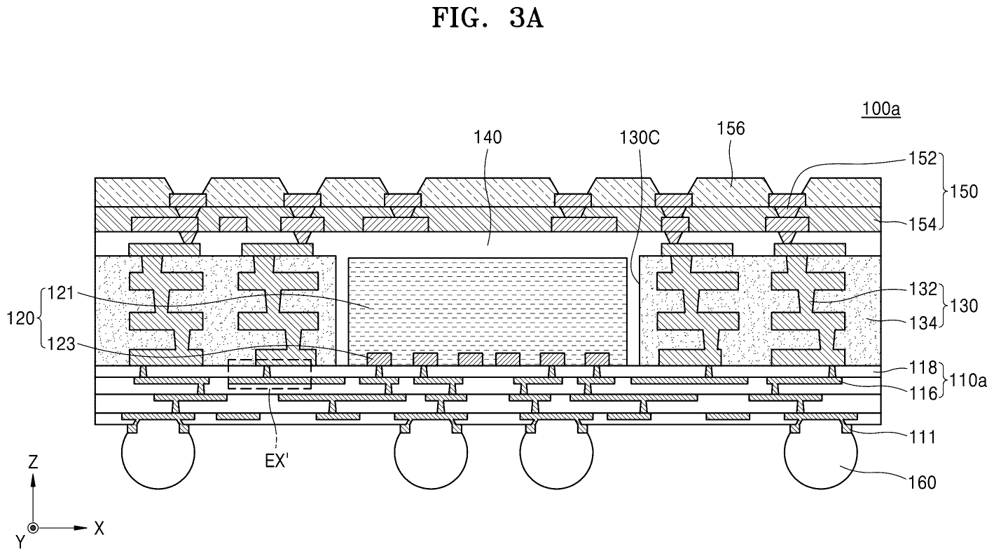

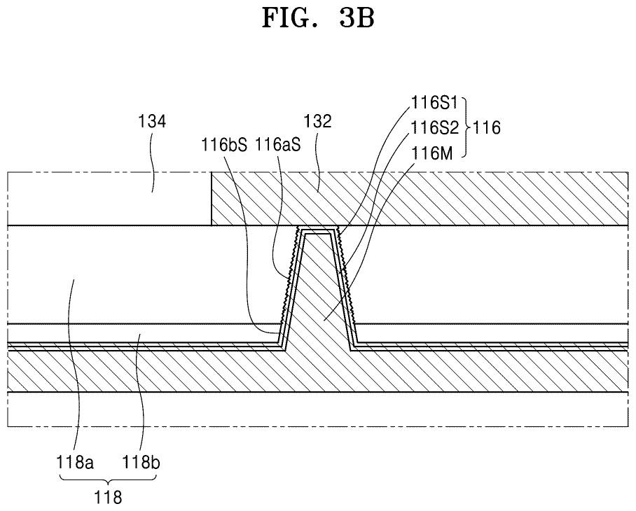

FIG. 3A is a cross-sectional view of a semiconductor package 100a according to some embodiments, and FIG. 3B is an enlarged cross-sectional view of portion EX′ of FIG. 3A. In FIGS. 3A and 3B, the same reference numerals as in FIGS. 2A and 2B indicate the same members, and descriptions thereof are omitted.

Referring to FIGS. 3A and 3B, the semiconductor package 100a is substantially the same as the semiconductor package 100 illustrated in FIGS. 2A and 2B except that the semiconductor package 100a includes a first redistribution structure 110a instead of the first redistribution structure 110 (see FIG. 2A).

The first redistribution structure 110a may include first redistribution patterns 116 and a first redistribution insulating layer 118.

The first redistribution insulating layer 118 may include a first insulating layer 118a and a second insulating layer 118b. The first insulating layer 118a may be an insulating layer formed by using the insulating resin layer 17 of the build-up film 10 illustrated in FIG. 1, and the second insulating layer 118b may be an insulating layer formed by using the protective layer 15 of the build-up film 10 illustrated in FIG. 1. In some embodiments, the first insulating layer 118a may include substantially the same material as the insulating resin layer 17 (see FIG. 1) of the build-up film 10, and the second insulating layer 118b may include substantially the same material as the protective layer 15 (see FIG. 1) of the build-up film 10. For example, the first insulating layer 118a may include epoxy resin, and the second insulating layer 118b may include silicon oxide.

In some embodiments, a bottom surface of the first insulating layer 118a may be a flat surface without surface roughness (e.g., smooth). In some embodiments, a bottom surface of the second insulating layer 118b may be a flat surface without surface roughness (e.g., smooth).

The first redistribution pattern 116 may include a plurality of first redistribution lines and a plurality of first redistribution vias. The first redistribution lines may extend in the horizontal direction (X direction) on the top surface or bottom surface of the first redistribution insulating layer 118. For example, the first redistribution vias may penetrate the first insulating layer 118a and extend into the second insulating layer 118b in the vertical direction (Z direction). Some of the first redistribution lines may be at different vertical levels (i.e., height) from the other first redistribution lines. The first redistribution vias may extend in the vertical direction (Z direction) within the first redistribution insulating layer 118. The first redistribution vias may contact each of the first insulating layer 118a and the second insulating layer 118b on both sides.

In some embodiments, a portion 116aS of a side surface of the first redistribution pattern 116 in contact with the first insulating layer 118a may be a curved surface with surface roughness. For example, a portion of the side surface of the second redistribution via included in the first redistribution pattern 116 in contact with the first insulating layer 118a may be a curved surface with surface roughness. In some embodiments, the other portion 116bS of the side surface of the first redistribution pattern 116 in contact with the second insulating layer 118b may be a flat surface without surface roughness (e.g., smooth). For example, a portion of the side surface of the second redistribution via included in the first redistribution pattern 116 in contact with the second insulating layer 118b may be a flat surface without surface roughness (e.g., smooth).

The first redistribution pattern 116 may include a first seed layer 116S1, a second seed layer 116S2, and a metal layer 116M. The first seed layer 116S1 may cover or overlap a portion of the surface of each of the first insulating layer 118a and the second insulating layer 118b. The first seed layer 116S1 may include, for example, Ti. The second seed layer 116S2 may be formed on the first seed layer 116S1 and may cover or overlap the first seed layer 116S1. The metal layer 116M may be formed on the second seed layer 116S2 and may cover or overlap the second seed layer 116S2. The second seed layer 116S2 and the metal layer 116M may each include Cu. A portion of each of the first seed layer 116S1, the second seed layer 116S2, and the metal layer 116M may form the second redistribution via of the first redistribution pattern 116, and the other portion of each of the first seed layer 116S1, the second seed layer 116S2, and the metal layer 116M may form the second redistribution line of the first redistribution pattern 116.

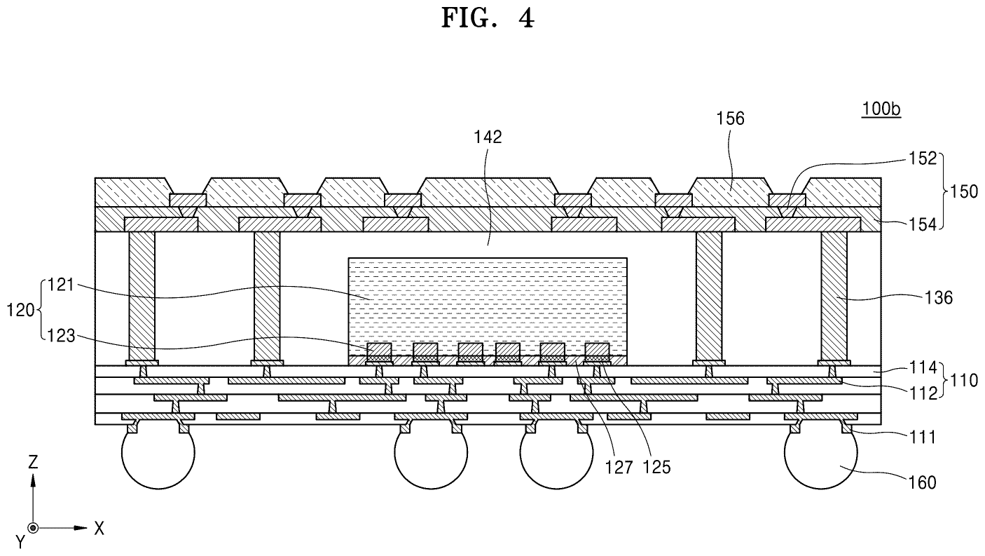

FIG. 4 is a cross-sectional view of a semiconductor package 100b according to some embodiments. In FIG. 4, the same reference numerals as in FIGS. 2A and 2B indicate the same members, and descriptions thereof are omitted.

Referring to FIG. 4, the semiconductor package 100b is substantially the same as the semiconductor package 100 illustrated in FIGS. 2A and 2B except that the semiconductor package 100b has a fan-out wafer level package (FOWLP) structure.

The semiconductor package 100b may include a first redistribution structure 110, a semiconductor chip 120, a plurality of conductive posts 136, a molding layer 142, and a second redistribution structure 150.

The plurality of conductive posts 136 may each be disposed on the first redistribution structure 110. The plurality of conductive posts 136 may be horizontally spaced apart from the semiconductor chip 120 mounted on the first redistribution structure 110. Bottom surfaces of the plurality of conductive posts 136 may contact some of the first redistribution patterns 112 of the first redistribution structure 110, and top surfaces thereof may contact some of the second redistribution patterns 152 of the second redistribution structure 150. The plurality of conductive posts 136 may connect the first redistribution structure 110 to the second redistribution structure 150. Each of the plurality of conductive posts 136 may include Cu, but is not limited thereto.

The molding layer 142 may at least partially fill a space between the semiconductor chip 120 and each of the plurality of conductive posts 136. In some embodiments, the molding layer 142 may include an epoxy-based material, a thermosetting material, or a thermoplastic material. For example, the molding layer 142 may include ABF, FR-4, BT, EMC, or a combination thereof.

A plurality of connection terminals 125 may be placed between the semiconductor chip 120 and the first redistribution structure 110. Top surfaces of the plurality of connection terminals 125 may contact the chip pads 123 of the semiconductor chip 120, and bottom surfaces thereof may contact some of the first redistribution patterns 112 of the first redistribution structure 110. The plurality of connection terminals 125 may connect the semiconductor chip 120 to the first redistribution structure 110. Each of the plurality of connection terminals 125 may include, for example, at least one of solder, Sn, Ag, Cu, and Al.

In some embodiments, an underfill material layer 127 may be placed between the bottom surface of the semiconductor chip 120 and the top surface of the first redistribution structure 110. The underfill material layer 127 may at least partially fill the space between the bottom surface of the semiconductor chip 120 and the top surface of the first redistribution structure 110 and may surround the plurality of connection terminals 125 in plan view. In some embodiments, the underfill material layer 127 may be omitted. In this case, the molding layer 142 may at least partially fill the space between the bottom surface of the semiconductor chip 120 and the top surface of the first redistribution structure 110 and may surround the plurality of connection terminals 125.

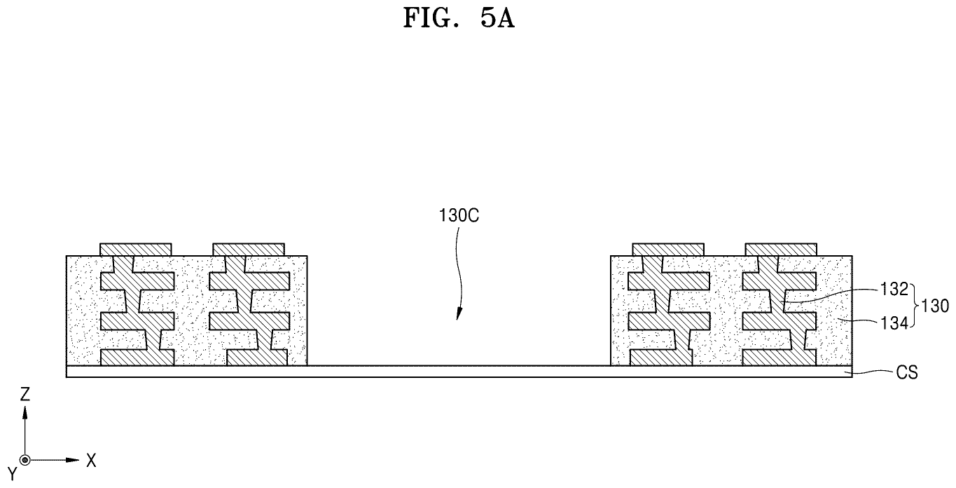

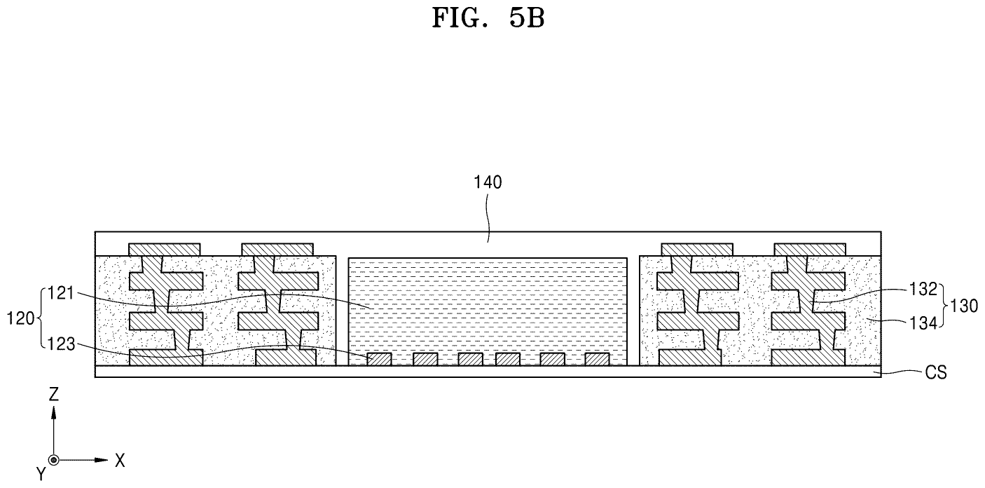

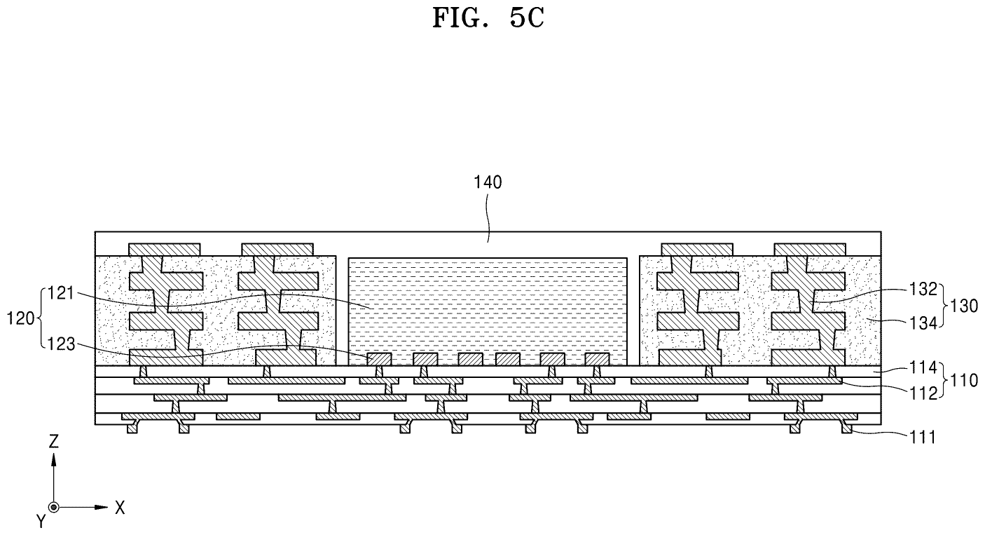

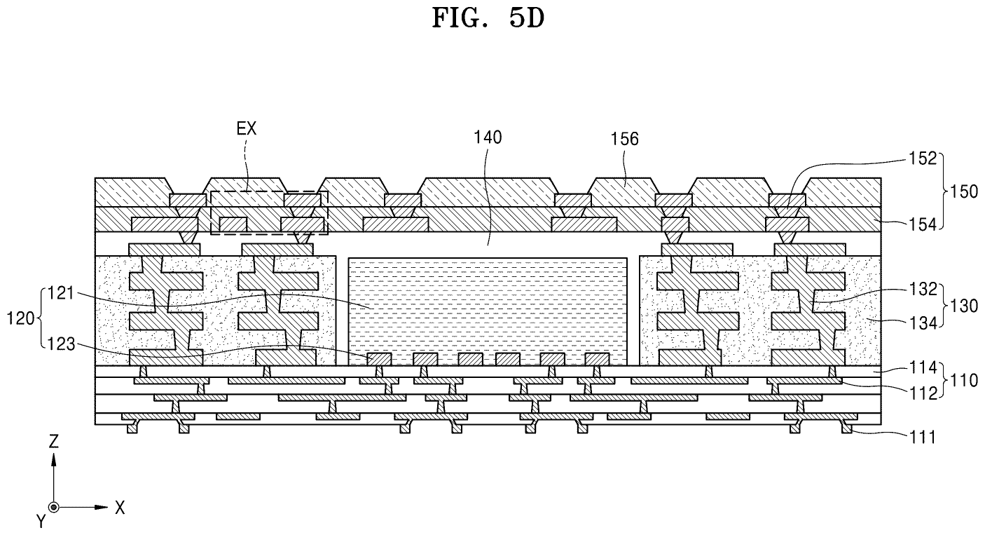

FIGS. 5A, 5B, 5C, and 5D are cross-sectional views illustrating a method of manufacturing a semiconductor package 100, according to some embodiments.

Referring to FIG. 5A, after the connection structure 130 with the cavity 130C is formed, the connection structure 130 may be attached to a support film CS. In some embodiments, the support film CS may include ABF.

Referring to FIG. 5B, in the result of FIG. 5A, the semiconductor chip 120 may be placed in the cavity 130C of the connection structure 130. The semiconductor chip 120 may be placed in the cavity 130C of the connection structure 130 so that one side of the semiconductor chip 120, on which the chip pads 123 are formed, faces the support film CS. The semiconductor chip 120 may be horizontally spaced apart from an inner wall of the cavity 130C.

Next, the molding layer 140 may be formed to at least partially fill the space between the semiconductor chip 120 and the cavity 130C and to cover or overlap the top surface of each of the semiconductor chip 120 and the connection structure 130.

Referring to FIG. 5C, in the result of FIG. 5B, the support film CS (see FIG. 5B) attached to the connection structure 130 may be removed.

Next, the first redistribution structure 110 may be formed on one surface of the semiconductor chip 120, on which the chip pads 123 are formed. The first redistribution structure 110 may be formed by repeatedly performing the process of forming the first redistribution insulating layer 114 on one surface of the semiconductor chip 120, on which the chip pads 123 are formed, forming a through hole (not shown) penetrating the first redistribution insulating layer 114 in the vertical direction (Z direction), and forming the first redistribution pattern 112 to at least partially fill the through hole and cover a portion of the top surface of the first redistribution insulating layer 114.

In some embodiments, the first redistribution pattern 112 may be formed by using a plating process. The plating process may include, for example, electroplating, electroless plating, or electrolytic plating.

Referring to FIG. 5D, in the result of FIG. 5C, the second redistribution structure 150 may be formed on the molding layer 140. A method of manufacturing the second redistribution structure 150 is described in detail with reference to FIGS. 6A, 6B, 6C, 6D, 6E, 6F, 6G, 6H, and 6I.

Next, the upper insulating layer 156 may be formed on the second redistribution structure 150. The upper insulating layer 156 may include a plurality of holes exposing uppermost second redistribution patterns 152 among the second redistribution patterns 152 of the second redistribution structure 150.

Next, in the result of FIG. 5D, the semiconductor package 100 illustrated in FIGS. 2A and 2B may be manufactured by forming the external connection terminals 160 disposed on the bottom surface of the first redistribution structure 110.

Hereinafter, a method of manufacturing the second redistribution structure 150 is described in more detail with reference to FIGS. 6A, 6B, 6C, 6D, 6E, 6F, 6G, 6H, and 6I.

FIGS. 6A, 6B, 6C, 6D, 6E, 6F, 6G, 6H, and 6I are enlarged cross-sectional views of portion EX of FIG. 5D illustrating a method of manufacturing the second redistribution structure 150 included in the semiconductor package 100. In FIGS. 6A, 6B, 6C, 6D, 6E, 6F, 6G, 6H, and 6I, a process of forming the second redistribution insulating layer 154 and the second redistribution pattern 152 on the second redistribution pattern 152 formed on the molding layer 140 is illustrated, but is not limited thereto.

Referring to FIG. 6A, the build-up film 10 from which the protective film 19 has been peeled may be provided, wherein the protective film 19 of the build-up film 10 illustrated in FIG. 1 is first peeled from the surface of the insulating resin layer 17, and the exposed insulating resin layer 17 faces the second redistribution patterns 152 formed on the molding layer 140. Next, a lamination process may be performed to allow the insulating resin layer 17 to at least partially fill a space between the second redistribution patterns 152 formed on the molding layer 140. After the lamination process is performed, the insulating resin layer 17 that at least partially fills the space between the second redistribution patterns 152 formed on the molding layer 140 may be defined as the first insulating layer 154a, and the protective layer 15 disposed on the insulating resin layer 17 may be defined as the second insulating layer 154b.

Referring to FIG. 6B, in the result of FIG. 6A, the support film 11 (see FIG. 6A) and the release layer 13 (see FIG. 6A) may be removed. Next, a first photoresist pattern PR1 may be formed on the second insulating layer 154b. The first photoresist pattern PR1 may expose a portion of the second insulating layer 154b that overlaps the second redistribution pattern 152 formed on the molding layer 140 in the vertical direction (Z direction). The first photoresist pattern PR1 may be, for example, a dry film photoresist, but is not limited thereto.

Referring to FIG. 6C, in the result of FIG. 6B, a portion of the second insulating layer 154b that overlaps the second redistribution pattern 152 formed on the molding layer 140 in the vertical direction (Z direction) may be removed using the first photoresist pattern PR1. By removing a portion of the second insulating layer 154b, a portion of the first insulating layer 154a that overlaps the second redistribution pattern 152 formed on the molding layer 140 in the vertical direction (Z direction) may be exposed. In some embodiments, a portion of the second insulating layer 154b may be removed by wet etching.

Referring to FIG. 6D, in the result of FIG. 6C, a portion of the first insulating layer 154a that overlaps the second redistribution pattern 152 formed on the molding layer 140 in the vertical direction (Z direction) may be removed. By removing a portion of the first insulating layer 154a, a through hole 154H that penetrates the second insulating layer 154b and extends into the first insulating layer 154a may be formed. The second redistribution pattern 152 formed on the molding layer 140 may be exposed at a bottom surface of the through hole 154H. In some embodiments, a portion of the first insulating layer 154a may be removed by plasma etching.

Next, the desmear process may be performed on the first insulating layer 154a and the second insulating layer 154b. The desmear process may be performed on the top surface of the second insulating layer 154b and the surface of each of the first insulating layer 154a and the second insulating layer 154b exposed by the through hole 154H. In this case, since the second insulating layer 154b includes an inorganic material, surface roughness may not be formed on the surface of the second insulating layer 154b by the desmear process. In addition, since the top surface of the first insulating layer 154a is covered or overlapped by the second insulating layer 154b, surface roughness may not be formed on the top surface of the first insulating layer 154a even when the desmear process is performed. On the other hand, since the first insulating layer 154a includes an organic material, surface roughness may be formed by the desmear process on the surface of the first insulating layer 154a exposed by the through hole 154H.

Next, the first photoresist pattern PR1 may be removed from the top surface of the second insulating layer 154b.

Referring to FIG. 6E, in the result of FIG. 6D, the first seed layer 152S1 and the second seed layer 152S2 may be sequentially formed on the top surface of the second insulating layer 154b and on the surface of each of the first insulating layer 154a and the second insulating layer 154b exposed by the through hole 154H. In some embodiments, the first seed layer 152S1 and the second seed layer 152S2 may each be formed by sputtering.

Referring to FIG. 6F, in the result of FIG. 6E, a second photoresist pattern PR2 may be formed on the second seed layer 152S2. The second photoresist pattern PR2 may expose a portion of the second seed layer 152S2. The second photoresist pattern PR2 may be, for example, a dry film photoresist, but is not limited thereto.

Referring to FIG. 6G, in the result of FIG. 6F, the metal layer 152M may be formed to at least partially fill the through hole 154H. In some embodiments, the metal layer 152M may be formed by electrolytic plating or electroless plating, but is not limited thereto.

Referring to FIG. 6H, in the result of FIG. 6G, the second photoresist pattern PR2 may be removed from the second seed layer 152S2. The second photoresist pattern PR2 may be removed by, for example, a strip process.

Referring to FIG. 6I, in the result of FIG. 6H, a portion of each of the first seed layer 152S1 and the second seed layer 152S2 may be removed. Each of the first seed layer 152S1 and the second seed layer 152S2 may be removed, for example, by an etching process. The first and second seed layers 152S1 and 152S2 that remain may form the second redistribution pattern 152 together with the metal layer 152M. In the process of manufacturing the semiconductor package 100 described with reference to FIG. 6I, the first seed layer 152S1 and the second seed layer 152S2 formed on the top surface of the second insulating layer 154b, which is a flat surface without surface roughness (e.g., smooth), may be removed. Compared to the case of removing a seed layer formed on a curved surface with surface roughness, when the seed layer formed on a flat surface without surface roughness (e.g., smooth) is removed, the amount of the seed layer to be removed is relatively small, which may be advantageous for implementing a fine redistribution pattern.

In some embodiments, the process of manufacturing the semiconductor package described with reference to FIGS. 6B and 6C may be omitted. In this case, after the lamination process described with reference to FIG. 6A is performed, a portion of each of the first insulating layer 154a and the second insulating layer 154b overlapping the second redistribution pattern 152 formed on the molding layer 140 in the vertical direction may be removed by laser etching, and after the desmear process is performed on the surface of each of the first insulating layer 154a and the second insulating layer 154b exposed by the laser etching, the process of manufacturing the second redistribution structure 150 described with reference to FIGS. 6E, 6F, 6G, 6H, and 6I may be performed. In some embodiments, the laser etching may be an etching process using CO2 gas. When the process of manufacturing the semiconductor package described with reference to FIGS. 6B and 6C is omitted and the laser etching is performed, the second redistribution structure 150 may be manufactured quickly, thereby improving the productivity of the process of manufacturing the semiconductor package 100.

While the inventive concept has been particularly shown and described with reference to embodiments thereof, it will be understood that various changes in form and details may be made therein without departing from the spirit and scope of the following claims.

What is claimed is:

1. A wiring structure comprising:
a wiring insulating layer comprising a first insulating layer and a second insulating layer on the first insulating layer; and
a wiring pattern that penetrates the second insulating layer and extends into the first insulating layer,
wherein a portion of a side surface of the wiring pattern in contact with the first insulating layer comprises a curved surface with a first surface roughness, and
wherein a portion of the side surface of the wiring pattern in contact with the second insulating layer comprises a flat surface with a second surface roughness that is less than the first surface roughness.

2. The wiring structure of claim 1, wherein a top surface of the first insulating layer is a flat surface that has a third surface roughness that is less than the first surface roughness.

3. The wiring structure of claim 1, wherein a top surface of the second insulating layer is a flat surface that has a fourth surface roughness that is less than the first surface roughness.

4. The wiring structure of claim 1, wherein the first insulating layer comprises an organic material, and the second insulating layer comprises an inorganic material.

5. The wiring structure of claim 1, wherein the wiring pattern comprises a first seed layer on a surface of each of the first insulating layer and the second insulating layer, a second seed layer on the first seed layer, and a metal layer on the second seed layer.

6. A semiconductor package comprising:
a first redistribution structure comprising a first redistribution insulating layer and a first redistribution pattern;
a semiconductor chip on the first redistribution structure; and
a second redistribution structure on the semiconductor chip and comprises a second redistribution insulating layer comprising a first insulating layer and a second insulating layer on the first insulating layer, and a second redistribution pattern that penetrates the second insulating layer and extends into the first insulating layer,
wherein a portion of a side surface of the second redistribution pattern in contact with the first insulating layer comprises a curved surface with a first surface roughness, and a portion of the side surface of the second redistribution pattern in contact with the second insulating layer comprises a flat surface with a second surface roughness that is less than the first surface roughness.

7. The semiconductor package of claim 6, wherein a top surface of the first insulating layer is a flat surface that has a third surface roughness that is less than the first surface roughness, and
wherein a top surface of the second insulating layer is a flat surface that has a fourth surface roughness that is less than the first surface roughness.

8. The semiconductor package of claim 6,
wherein the second insulating layer comprises an inorganic material such that a difference in a thermal expansion coefficient between the second redistribution structure and the semiconductor chip is reduced compared to when the second insulating layer includes an organic material.

9. The semiconductor package of claim 6, wherein the first insulating layer comprises an organic material, and the second insulating layer comprises an inorganic material.

10. The semiconductor package of claim 6, wherein the second redistribution pattern comprises a first seed layer on a surface of each of the first insulating layer and the second insulating layer, a second seed layer on the first seed layer, and a metal layer on the second seed layer.

11. The semiconductor package of claim 6, further comprising:
a connection structure on the first redistribution structure and on sidewalls of the semiconductor chip.

12. The semiconductor package of claim 6, further comprising:
a plurality of conductive posts on the first redistribution structure and electrically connecting the first redistribution structure to the second redistribution structure.

13. The semiconductor package of claim 6, wherein the first redistribution insulating layer comprises a first insulating layer and a second insulating layer on a bottom surface of the first insulating layer,
wherein the first redistribution pattern penetrates the first insulating layer and extends into the second insulating layer, and
wherein a portion of a side surface of the first redistribution pattern in contact with the first insulating layer comprises a curved surface with surface roughness, and a portion of a side surface of the second redistribution pattern in contact with the second insulating layer comprises a flat surface that has a third surface roughness that is less than the first surface roughness.

14. The semiconductor package of claim 13, wherein the bottom surface of the first insulating layer is a flat surface without surface roughness.

15. The semiconductor package of claim 13, wherein a bottom surface of the second insulating layer is a flat surface without surface roughness.

16. The semiconductor package of claim 14, wherein the first insulating layer comprises an organic material, and the second insulating layer comprises an inorganic material.

17. The semiconductor package of claim 14, wherein the first redistribution pattern comprises a first seed layer on a surface of each of the first insulating layer and the second insulating layer, a second seed layer on the first seed layer, and a metal layer on the second seed layer.

18. A semiconductor package comprising:
a first redistribution structure comprising a first redistribution insulating layer and a first redistribution pattern;
a semiconductor chip on the first redistribution structure;
a connection structure on the first redistribution structure and on side surfaces of the semiconductor chip;
a molding layer that at least partially fills a space between the semiconductor chip and the connection structure and is on a top surface of each of the semiconductor chip and the connection structure; and
a second redistribution structure on the semiconductor chip and comprises a second redistribution insulating layer comprising a first insulating layer and a second insulating layer on the first insulating layer, and a second redistribution pattern that penetrates the second insulating layer and extends into the first insulating layer,
wherein a portion of a side surface of the second redistribution pattern in contact with the first insulating layer comprises a curved surface with a first surface roughness, and a portion of the side surface of the second redistribution pattern in contact with the second insulating layer comprises a flat surface with a second surface roughness that is less than the first surface roughness.

19. The semiconductor package of claim 18, wherein the first insulating layer comprises epoxy resin, and the second insulating layer comprises silicon oxide.

20. The semiconductor package of claim 18, wherein the first insulating layer has a thickness of about 50 μm to about 60 μm, and the second insulating layer has a thickness of about 10 nm to about 5000 nm.
